(19) United States
(12) Patent Application Publication
(10) Pub. No.: US 2026/0190795 A1
(43) Pub. Date: Jul. 2, 2026

(54) DISPLAY DEVICE

(71) Applicant: LG Display Co., Ltd., Seoul (KR)

(72) Inventors: ChangHyun SONG, Paju-si (KR); Seunghwan KIM, Paju-si (KR); Seonhee LEE, Paju-si (KR)

(73) Assignee: LG Display Co., Ltd., Seoul (KR)

(21) Appl. No.: 19/347,423

(22) Filed: Oct. 1, 2025

(30) Foreign Application Priority Data
Dec. 27, 2024 (KR) 10-2024-0198670

(51) Int. Cl. H10K 59/80; H10K 59/122

(52) U.S. Cl. CPC H10K 59/874; H10K 59/122; H10K 59/873

(57) ABSTRACT

A display device can include a base substrate including a display area and a non-display area, a first metal layer disposed on the non-display area of the base substrate, a plurality of organic layers disposed on the base substrate and having a hole for exposing a portion of the first metal layer in the non-display area, a second metal layer contacting the first metal layer through the hole, an edge portion of the second metal layer being disposed between the organic layers located outside of the hole with respect to the hole, a contact electrode contacting the second metal layer through the hole, an edge portion of the contact electrode being disposed between the organic layers located outside of the hole with respect to the hole, a protection layer covering the plurality of organic layers, and an encapsulation layer disposed on the protection layer.

### CROSS REFERENCE TO RELATED APPLICATION

This application claims priority to Korean Patent Application No. 10-2024-0198670, filed on December 27, 2024 in the Korean Intellectual Property Office, which is hereby expressly incorporated by reference for all purposes as if fully set forth herein into the present application.

### BACKGROUND

### Field

The present disclosure relates to electronic devices, and more specifically, to display devices.

### Discussion of the Related Art

In today's information society, display devices for presenting images or visual information to users are increasingly important. The needs for such display devices has caused display technology to be rapidly developed, and various types or usages of display devices being thinner and lighter, consuming low power, and having excellent performance have been developed.

For example, a liquid crystal display (LCD) device, an organic light emitting display (OLED) device, a plasma display device (PDP), a field emission display (FED) device, an inorganic light emitting display (iLED) device, a micro light emitting display (micro LED) device, a mini light emitting display (mini LED) device, a quantum dot light emitting display (QLED) device, and the like, have been developed and become increasingly advanced.

Recently, work has been progressing on designing display devices with a larger display area. For example, research and development has been progressing on implementing a narrow bezel structure of providing users with a wider and larger display area by minimizing a bezel where images are not displayed and increasing a display area where images are displayed.

### SUMMARY OF THE DISCLOSURE

One or more aspects of the present disclosure can provide a display device that includes a structure where one or more organic layers disposed in a non-display area have a hole and thereby serve as a dam, and is capable of enabling the display device to have a narrow bezel.

One or more aspects of the present disclosure can provide a display device that includes a structure where one or more organic layers disposed in a non-display area have a hole, and a portion of an encapsulation layer is disposed in the hole, and is capable of preventing a material of the encapsulation layer from overflowing outwardly from the organic layer.

One or more aspects of the present disclosure can provide a display device that includes a structure where a hole is formed in one or more organic layers disposed in a non-display area, and thereafter, a plurality of electrodes and metal layers are electrically connected in the hole, and is capable of enabling the display device to have a narrow bezel.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device can include a base substrate including a display area and a non-display area, a first metal layer disposed on the non-display area of the base substrate, a plurality of organic layers disposed on the base substrate and having a hole for exposing a portion of the first metal layer in the non-display area, a second metal layer contacting the first metal layer through the hole, an edge portion of the second metal layer being disposed between the organic layers located outside of the hole with respect to the hole, a contact electrode contacting the second metal layer through the hole, an edge portion of the contact electrode being disposed between the organic layers located outside of the hole with respect to the hole, a protection layer covering the plurality of organic layers, and an encapsulation layer disposed on the protection layer and including a portion located in the hole.

According to one or more aspects of the present disclosure, a display device can be capable of enabling the display device to have a narrow bezel by including a structure where one or more organic layers disposed in a non-display area has a hole and thereby serve as a dam.

According to one or more aspects of the present disclosure, a display device can be capable of preventing a material of an encapsulation layer from overflowing outwardly from an organic layer by including a structure where one or more organic layers disposed in a non-display area have a hole, and a portion of the encapsulation layer is disposed in the hole.

According to one or more aspects of the present disclosure, a display device can be capable of enabling the display device to have a narrow bezel by including a structure where a hole is formed in one or more organic layers disposed in a non-display area, and thereafter, a plurality of electrodes and metal layers are electrically connected in the hole.

According to one or more aspects of the present disclosure, a display device can be capable of reducing a width of a bezel area by an area of a dam, and thereby, enabling the display device to become lighter.

Effects or advantages from aspects, examples, and embodiments described herein are not limited thereto, and additional effects or advantages will become apparent to those skilled in the art from the following description.

### BRIEF DESCRIPTION OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 illustrates an example system configuration of a display device according to aspects of the present disclosure;

FIG. 2 is a cross-sectional view taken along line A-A' of the display device shown in FIG. 1;

FIG. 3 is a cross-sectional view taken along line B-B' of the display device shown in FIG. 1; and

FIG. 4 is an example cross-sectional view of a portion of the display device of FIG. 3 according to aspects of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents.

In the following description, where the detailed description of the relevant known function or configuration can unnecessarily obscure aspects of the present disclosure, a detailed description of such known function or configuration can be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present invention. These terms are used only to distinguish one element from another. For example, a first element could be termed a second element, and, similarly, a second element could be termed a first element, without departing from the scope of the present disclosure.

When it is mentioned that a first element "is connected or coupled to", “contacts or overlaps” etc. a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc. each other via a fourth element. Here, the second element can be included in at least one of two or more elements that "are connected or coupled to", “contact or overlap”, etc. each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, with reference to the accompanying drawings, various embodiments of the present disclosure will be described in detail. All the components of each display device according to all embodiments of the present disclosure are operatively coupled and configured.

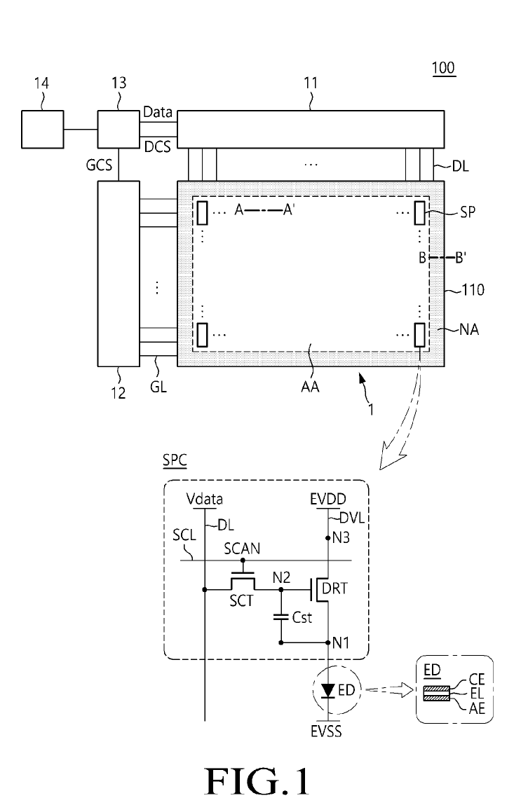

FIG. 1 illustrates an example system configuration of a display device according to aspects of the present disclosure.

Referring to FIG. 1, in one or more example embodiments, a display driving system of the display device 100 can include a display panel 1 and at least one display driving circuit for driving the display panel 1.

The display panel 1 can include a display area AA (or active area) in which an image can be displayed and a non-display area NA (non-active area) in which an image is not displayed. The non-display area NA can be an area outside of the display area AA, and can also be referred to as a non-active area or a bezel area. All or at least part of the non-display area NA can be an area visible in front of the display device 100, or an area invisible in front of the display device 100 while being bent.

The display panel 1 can include a plurality of subpixels SP disposed on a base substrate 110 for displaying images. The display panel 1 can include a plurality of signal lines to drive the plurality of subpixels SP. For example, the plurality of signal lines can include data lines DL, gate lines GL, driving voltage lines DVL, and the like.

Each data line DL can be disposed to extend in a first direction (e.g., a column direction or a row direction), and each gate line GL can be disposed to extend in a direction intersecting the first direction.

The at least one display driving circuit can include a data driving circuit 11 and a gate driving circuit 12, and can further include a controller 13 for controlling the data driving circuit 11 and the gate driving circuit 12.

The data driving circuit 11 can output data signals (which can be also referred to as data voltages) corresponding to image signals to the data lines DL. The gate driving circuit 12 can generate gate signals and output the gate signals to the gate lines GL. The controller 13 can convert image data received from an external host 14 to a data signal form readable by the data driving circuit 11, and then supply image data Data resulting from the converting to the data driving circuit 11.

The data driving circuit 11 can include one or more source driver integrated circuits. For example, each source driver integrated circuit can be connected to the display panel 1 by a tape-automated-bonding (TAB) technique, or connected to a conductive pad such as a bonding pad of the display panel 1 by a chip-on-glass (COG) technique or a chip-on-panel (COP) technique, or connected to the display panel 1 by a chip-on-film (COF) technique.

The gate driving circuit 12 can be connected to the display panel 1 by the tape-automated-bonding (TAB) technique, or connected to a conductive pad such as a bonding pad of the display panel 1 by the chip-on-glass (COG) technique or the chip-on-panel (COP) technique, or connected to the display panel 110 by the chip-on-film (COF) technique, or formed in the non-display area NA of the display panel 1 by a gate-in-panel (GIP) technique.

In one or more aspects, each of a plurality of subpixels SP included in the display device 100 can include a light emitting element ED and a pixel driving circuit SPC for driving the light emitting element ED. The pixel driver circuit SPC can include a driving transistor DRT, a scan transistor SCT, and a storage capacitor Cst.

The driving transistor DRT can control current flowing to the light emitting element ED to drive the light emitting element ED. The scan transistor SCT can transfer a data voltage Vdata to a second node N2, which is the gate node of the driving transistor DRT. The storage capacitor Cst can maintain a voltage at a certain level for a predefined period of time.

The light emitting element ED can include a first electrode AE, a second electrode CE, and an emission layer EL located between the first electrode AE and the second electrode CE. The first electrode AE can be a pixel electrode included in a corresponding light emitting element ED of each of a plurality of subpixels SP, and be electrically connected to a first node N1 of the driving transistor DRT. The second electrode CE can be a common electrode included in corresponding light emitting elements ED of all or some of a plurality of subpixels SP, and a base voltage EVSS can be applied to the second electrode CE.

For example, the light emitting element ED can be an organic light emitting diode (OLED), an inorganic-based light emitting diode (LED), or a quantum dot light emitting element, which is a semiconductor crystal that emits light on its own.

The driving transistor DRT can be a transistor for driving the light emitting element ED, and include a first node N1, a second node N2, and a third node N3. The first node N1 can be a source or drain node and be electrically connected to the first electrode AE of the light emitting element ED. The second node N2 can be the gate node and be electrically connected to the source or drain node of the scan transistor SCT. The third node N3 can be the drain or source node and be electrically connected to a driving voltage line DVL for delivering a driving voltage EVDD. Hereinafter, for convenience of explanation, discussions are provided based on examples where the first node N1 and the third node N3 are the source node and the drain node, respectively.

The scan transistor SCT can switch a connection between a data line DL and the second node N2 of the driving transistor DRT. The scan transistor SCT can control a connection between the second node N2 of the driving transistor DRT and a corresponding one of a plurality of data lines DL in response to a scan signal SCAN delivered through a scan line SCL, which is a type of gate line GL.

The storage capacitor Cst can be configured between the first node N1 and the second node N2 of the driving transistor DRT.

It should be noted that the structure of the subpixel SP illustrated in FIG. 1 is only an example for explanation, and can further include one or more transistors or one or more capacitors depending design requirements. For example, a plurality of subpixels can have the same structure, or some of the plurality of subpixels can have different structures from the remaining subpixels. Each of the driving transistor DRT and the scan transistor SCT can be an n-type transistor or a p-type transistor.

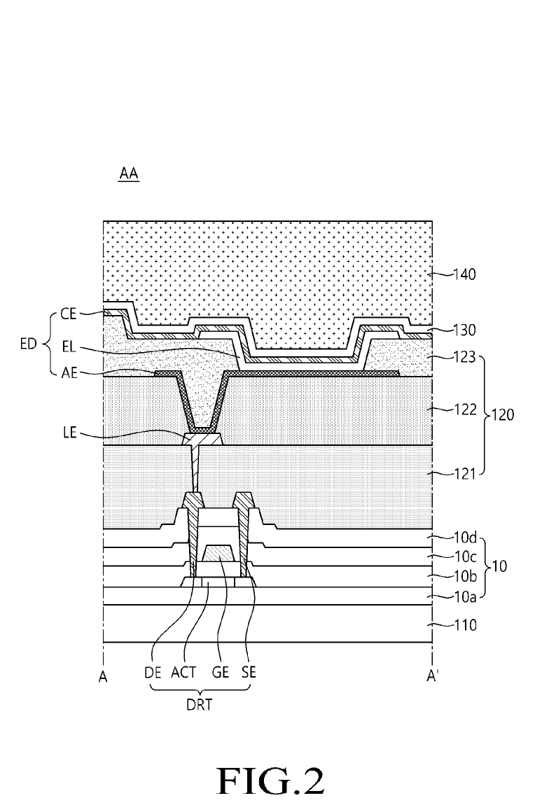

FIG. 2 is a cross-sectional view taken along line A-A' of the display device 100 shown in FIG. 1.

Referring to FIG. 2, in one or more example embodiments, the display area AA of the display device 100 can include a base substrate 110, a driving transistor DRT, a light emitting element ED, at least one organic layer 120, a protection layer 130, and an encapsulating layer 140.

For example, the base substrate 110 can be for supporting various elements of the display device 100, and include an insulating material such as a glass substrate or a plastic substrate. FIG. 2 illustrates that the base substrate 110 is in the form of one layer, but aspects of the present disclosure are not limited thereto. For example, the base substrate 110 can be in the form of a multi-layer.

The base substrate 110 can include at least one inorganic layer 10 in an upper portion thereof to block moisture and oxygen from penetrating inside of the display device 100 through the base substrate 110 and insulate configurations inside of the display device 100 against moisture and oxygen. The at least one inorganic layer 10 can be formed with a relatively thin thickness of micro (㎛) size, and therefore, each of the at least one inorganic layer 10 can be formed along a step of a structure located thereunder. Through at least one inorganic layer, the penetration of oxygen and moisture can be effectively blocked.

For example, the at least one inorganic layer 10 can include an inorganic material such as silicon nitride (SiNx), silicon oxide (SiOx), silicon oxynitride (SiON), aluminum oxide (Al₂O₃), or the like. The at least one inorganic layer 10 can include a buffer layer 10a, a first insulating layer 10b, a second insulating layer 10c, and a third insulating layer 10d.

The buffer layer 10a can improve an adhesive strength between one or more layers formed thereon and the base substrate 110, and can block an alkaline component leaking from the base substrate 110. FIG. 2 illustrates that the buffer layer 10a is in the form of a single layer, but aspects of the present disclosure are not limited thereto. For example, the buffer layer 10a can be in the form of a multi-layer.

A driving transistor DRT can be disposed on the buffer layer 10a. For example, the driving transistor DRT can include an active layer ACT, a gate electrode GE, a source electrode SE, and a drain electrode DE.

The active layer ACT is a semiconductor layer and be disposed on the buffer layer 10a. The active layer ACT can include a channel region, a source region, and a drain region. The channel region can overlap with the gate electrode GE with the first insulating layer 10b interposed therebetween to form the channel region between the source electrode SE and the drain electrode DE. The source region can be electrically connected to the source electrode SE, and the drain region can be electrically connected to the drain electrode DE.

The gate electrode GE can be disposed on the first insulating layer 10b and be covered by the second insulating layer 10c. For example, the gate electrode GE can overlap with the channel region of the active layer ACT with the first insulating layer 10b interposed therebetween. The gate electrode GE can be in the form of a single layer or multi-layer including at least one of molybdenum (Mo), aluminum (Al), chromium (Cr), gold (Au), titanium (Ti), nickel (Ni), neodymium (Nd), and copper (Cu), or at least one alloy thereof.

The source electrode SE can be disposed on the third insulating layer 10d, and be connected to the source region of the active layer ACT through a hole penetrating the third insulating layer 10d, the second insulating layer 10c, and the first insulating layer 10b.

The drain electrode DE can be disposed on the third insulating layer 10d to face the source electrode SE, and be connected to the drain region of the active layer ACT through a hole penetrating the third insulating layer 10d, the second insulating layer 10c, and the first insulating layer 10b.

The at least one organic layer 120 can be disposed on the at least one inorganic layer 10. The at least one organic layer 120 can be formed with a relatively thick thickness, and therefore, can alleviate a step of a structure located thereunder. The at least one organic layer 120 can prevent and cover the flow of particles generated during the process of manufacturing the display panel 1 or the display device 100. For example, the at least one organic layer 120 can include a first planarization layer 121, a second planarization layer 122, and a bank layer 123.

The first planarization layer 121 can include an organic material such as an acrylic resin, an epoxy resin, a phenolic resin, a polyamide resin, a polyimide resin, or the like, and cover the source electrode SE and the drain electrode DE on the third insulating layer 10d.

A connection electrode LE for interconnecting the light emitting element ED and the drain electrode DE can be disposed on the first planarization layer 121. For example, the first planarization layer 121 can include a contact hole, and the connection electrode LE and the source electrode SE or the drain electrode DE can be connected to each other through the contact hole.

The second planarization layer 122 can include an organic material such as an acrylic resin, an epoxy resin, a phenolic resin, a polyamide resin, a polyimide resin, or the like, and cover the connection electrode LE on the first planarization layer 121. For example, the second planarization layer 122 can include a contact hole, and the first electrode AE and the connection electrode LE can be connected to each other through the contact hole.

The light emitting element ED can be disposed on the second planarization layer 122. For example, the light emitting element ED can include a first electrode AE, which is an anode electrode, an emission layer EL, and a second electrode CE, which is a cathode electrode. The first electrode AE can be electrically connected to the connection electrode LE through the contact hole of the second planarization layer 122.

The bank layer 123 can define one or more pixels and be disposed on the second planarization layer 122. The bank layer 123 disposed in the display area AA can have an opening formed to expose the first electrode AE located thereunder. Accordingly, a portion of the first electrode AE can be exposed through the opening of the bank layer 123, and a lower side of the emission layer EL can contact an upper surface of the first electrode AE exposed by the opening.

The bank layer 123 can include a material including a black pigment, or an organic material such as a benzocyclobutene resin, a polyimide resin, an acrylic resin, a photosensitive polymer, or the like, but aspects of the present disclosure are not limited thereto. In an example where the bank layer 123 includes a material including a black pigment or a black dye, this bank layer 123 can be a black bank. When the bank layer 123 includes a material including a black pigment or a black dye, light from the outside or light reflected from the outside can be blocked, and thereby, the luminance of the display device 100 can be further improved.

The protection layer 130 can be disposed on the light emitting element ED such that the protection layer 130 covers the light emitting element ED. Thereby, the light emitting element ED can be protected from external moisture, oxygen, impact, and the like.

The protection layer 130 can include an inorganic material capable of being formed through a low-temperature deposition, such as silicon nitride (SiNx), silicon oxide (SiOx), silicon oxynitride (SiON), aluminum oxide (Al₂O₃), or the like. According to this configuration, when the protection layer 130 is deposited in a low-temperature atmosphere, the emission layer EL, which includes an organic material vulnerable to a high-temperature atmosphere, can be prevented from being damaged during the deposition process of the protection layer 130.

The encapsulation layer 140 can be disposed on the protection layer 130. For example, the encapsulation layer 140 can include an organic insulating material such as an acrylic resin, an epoxy resin, a polyimide, polyethylene, silicon oxycarbon (SiOC), or the like, but aspects of the present disclosure are not limited thereto. Since the encapsulation layer 140 includes an organic material, one or more elements disposed thereunder can be encapsulated, and at the same time, a step difference can be alleviated. A touch sensor can be disposed on the encapsulation layer 140.

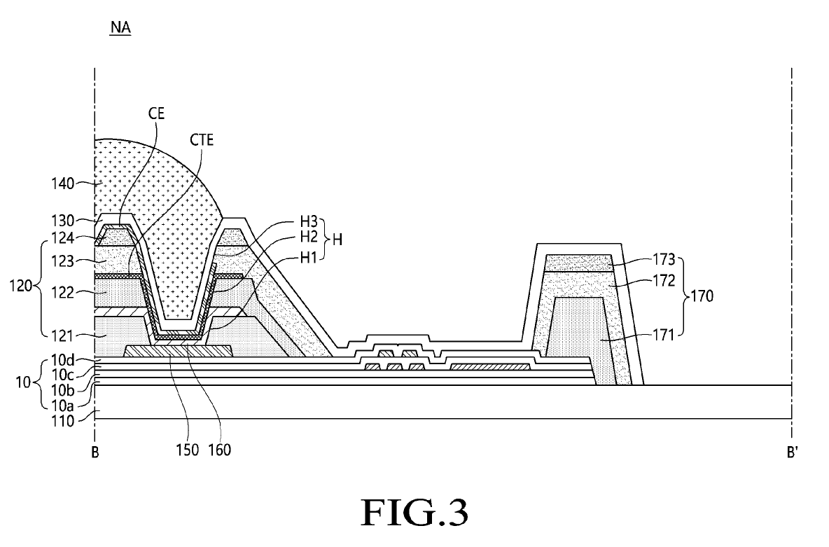

FIG. 3 is a cross-sectional view taken along line B-B' of the display device 100 shown in FIG. 1.

Referring to FIG. 3, in one or more example embodiments, the non-display area NA of the display device 100 can include the base substrate 110, the at least one organic layer 120, the protection layer 130, the encapsulation layer 140, a first metal layer 150, and a second metal layer 160.

The base substrate 110 can include at least one inorganic layer 10 in an upper portion thereof to block moisture and oxygen from penetrating inside of the display device 100 through the base substrate 110. For example, the at least one inorganic layer 10 can include an inorganic material such as silicon nitride (SiNx), silicon oxide (SiOx), silicon oxynitride (SiON), aluminum oxide (Al₂O₃), or the like. The at least one inorganic layer 10 can include a buffer layer 10a, a first insulating layer 10b, a second insulating layer 10c, and a third insulating layer 10d.

The first metal layer 150 can be disposed in the non-display area NA. For example, the first metal layer 150 can be disposed on the third insulating layer 10d included in the base substrate 110. The first metal layer 150 can include the same material as a source electrode SE and a drain electrode DE, and be electrically connected to a common voltage line.

The at least one organic layer 120 can be disposed on the base substrate 110, and a hole H can be formed to expose a portion of the first metal layer 150 in the non-display area NA. The hole H formed in the at least one organic layer 120 can be disposed to surround the display area AA in the non-display area NA. For example, the hole H can have a closed loop shape in a plan view. The shape of the hole H are not limited to thereto.

The first metal layer 150, the second metal layer 160, the contact electrode CTE, and the second electrode CE can overlap with each other in the hole H formed in the at least one organic layer 120, which will be described in more detail later.

The at least one organic layer 120 can include the first planarization layer 121, the second planarization layer 122, and the bank layer 123.

The first planarization layer 121 can be disposed on the base substrate 110, and have a first hole H1 formed in an area overlapping with the first metal layer 150. Accordingly, a portion of an upper surface of the first metal layer 150 can be exposed to the outside through the first hole H1. The second metal layer 160, the contact electrode CTE, and the second electrode CE can overlap with each other on an inclined surface of the first planarization layer 121 formed by the first hole H1.

The second planarization layer 122 can be disposed on the first planarization layer 121, and have a second hole H2 formed in an area overlapping with the first hole H1. For example, the second hole H2 of the second planarization layer 122 can be connected to the first hole H1 of the first planarization layer 121, and a width of the second hole H2 can be greater than a width of the first hole H1. The second metal layer 160 and the contact electrode CTE can overlap with each other on an inclined surface of the second planarization layer 122 formed by the second hole H2.

The second metal layer 160 can be disposed between the first planarization layer 121 and the second planarization layer 122. The second metal layer 160 can include the same material as the connection electrode LE, and a lower surface of the second metal layer 160 can contact an upper surface of the first metal layer 150 through the first hole H1. Accordingly, the second metal layer 160 and the first metal layer 150 can be electrically connected to each other.

The bank layer 123 can be disposed on the second planarization layer 122, and have a third hole H3 formed in an area overlapping with the second hole H2. For example, the third hole H3 of the bank layer 123 can be connected to the second hole H2 of the second planarization layer 122, and a width of the third hole H3 can be greater than a width of the second hole H2. The hole H of the at least one organic layer 120 can include the first hole H1, the second hole H2, and the third hole H3.

The bank layer 123 can further include a spacer 124 in an upper portion thereof to prevent damage caused by a mask used when forming an emission layer EL. The spacer 124 can include an organic material. For example, the spacer 124 can include the same material as the bank layer 123.

The contact electrode CTE can be disposed between the second planarization layer 122 and the bank layer 123. A lower surface of the contact electrode CTE can contact an upper surface of the second metal layer 160 through the first hole H1 and the second hole H2. Accordingly, the contact electrode CTE, the second metal layer 160, and the first metal layer 150 can be electrically connected to each other. The contact electrode CTE can include the same material as the first electrode AE.

An end portion of the second planarization layer 122 can cover respective end portions of the second metal layer 160 and the first planarization layer 121. As the end portion of the second planarization layer 122 covers the end portions of the second metal layer 160 and the first planarization layer 121, moisture can be prevented from flowing into the first metal layer 150 and the second metal layer 160.

The second electrode CE can be disposed on the bank layer 123. For example, the second electrode CE can be disposed between the bank layer 123 and the protection layer 130, and a lower surface of the second electrode CE can contact an upper surface of the contact electrode CTE through the first hole H1, the second hole H2, and the third hole H3. Accordingly, the second electrode CE, the contact electrode CTE, the second metal layer 160, and the first metal layer 150 can be electrically connected to each other.

According to these configurations, since the second electrode CE, the second metal layer 160, and the first metal layer 150 are electrically connected in one hole H formed in the at least one organic layer 120, a width of the non-display area NA can be reduced.

An end portion of the second electrode CE can be disposed on an inclined surface of the at least one organic layer 120 formed by the hole H. For example, the end portion of the second electrode CE can be disposed in the third hole H3 such that the end portion of the second electrode CE does not extend beyond the bank layer 123. This structure of the second electrode CE can reduce resistance by forming a contact area with the contact electrode CTE as great as possible. Further, since the end portion of the second electrode CE, which can be a path through which moisture passes, is not exposed outside of the bank layer 123, moisture permeability resistance can be improved.

An outer end portion of the bank layer 123 can cover respective outer end portions of the contact electrode CTE and the second planarization layer 122. Accordingly, moisture can be prevented from flowing into the contact electrode CTE, the first metal layer 150, and the second metal layer 160. In one or more aspects, the display device 100 can further include a moisture permeation prevention structure 170 spaced apart from the at least one organic layer 120.

The moisture permeation prevention structure 170 can be disposed on the base substrate 110, and cover an upper end portion and a side end portion of the inorganic layer 10. According to this configuration, since the moisture permeation prevention structure 170 covers the upper end portion and the side end portion of the inorganic layer 10, moisture can be prevented from flowing into an edge of the inorganic layer 10.

The moisture permeation prevention structure 170 can include a plurality of layers. For example, the moisture permeation prevention structure 170 can include a first moisture permeation prevention portion 171, a second moisture permeation prevention portion 172, and a third moisture permeation prevention portion 173, and include the same material as one selected from one or more materials included in the at least one organic layer 120.

In one or more aspects, the first moisture permeation prevention portion 171 can include the same material as the second planarization layer 122, and cover an upper end portion and a side end portion of the inorganic layer 10.

The second moisture permeation prevention portion 172 can include the same material as the bank layer 123, and cover an upper surface and at least one side surface of the first moisture permeation prevention portion 171.

The third moisture permeation prevention portion 173 can include the same material as the spacer 124, and cover an upper surface of the second moisture permeation prevention portion 172. When the third moisture permeation prevention portion 173 is formed to further cover at least one side surface of the second moisture permeation prevention portion 172, a width of the non-display area NA can increase. Therefore, the third moisture permeation prevention portion 173 can cover only the upper surface of the second moisture permeation prevention portion 172.

The protection layer 130 can include an inorganic material such as silicon nitride (SiNx), silicon oxide (SiOx), silicon oxynitride (SiON), aluminum oxide (Al₂O₃), or the like. The protection layer 130 can cover the second electrode CE, the at least one organic layer 120, the base substrate 110, and the moisture permeation prevention structure 170. At this configuration, an outer edge of the base substrate 110 on which the protection layer 130 is disposed can be an unnecessary portion, and therefore, be cut and removed.

The encapsulation layer 140 can be disposed on the protection layer 130. The inorganic protection layer 130 and the organic encapsulation layer 140 can prevent the penetration of oxygen and moisture. Therefore, the inorganic protection layer 130 and the organic encapsulation layer 140 can be referred to as an encapsulation part. The encapsulation part can cover respective upper portions of the protection layer 130 and the encapsulation layer 140, and further include a second encapsulation layer including an inorganic material.

An end portion of the encapsulation layer 140 can be disposed in the hole H. According to this configuration, since the end portion of the encapsulation layer 140 is disposed in the hole H, a material of the encapsulation layer 140 can be prevented from overflowing out of the at least one organic layer 120 during the process of manufacture the encapsulation layer 140. For example, the hole H formed in the at least one organic layer 120 can serve as a dam DAM. According to this configuration, since the same effect as a dam is formed through the hole H of the at least one organic layer 120 without forming a dam in the non-display area NA can be achieved, the flow of the encapsulation layer 140 can be controlled, and at the same time, a width of the non-display area NA can be reduced by a width of the dam, thereby enabling the implementation of a narrow bezel.

The hole H formed in the at least one organic layer 120 can be formed in a tapered shape with a width narrowing from the top to the bottom in a cross-sectional view. As the hole H is formed in the tapered shape, a contact area between the encapsulation layer 140 and the at least one organic layer 120 disposed in the hole H can be increased, this making it easier to control the flow of the encapsulation layer 140.

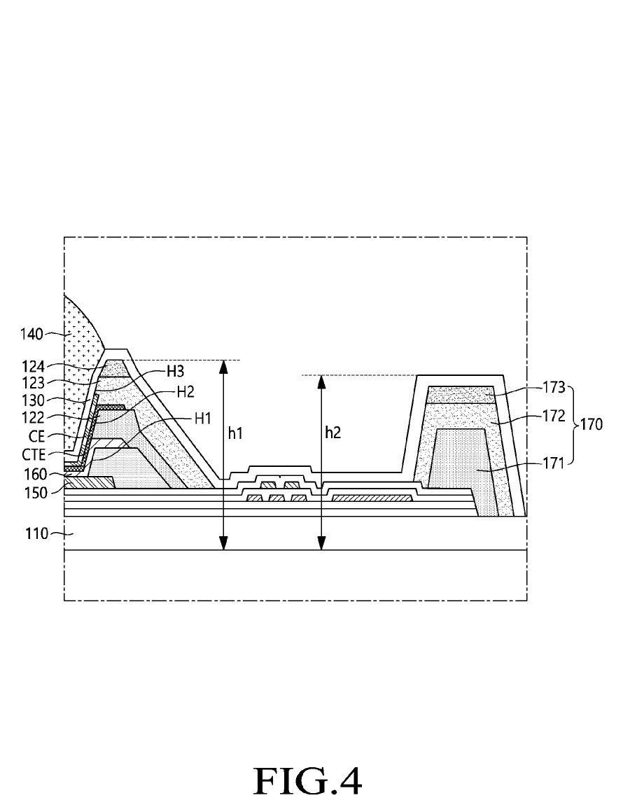

FIG. 4 is an example cross-sectional view of a portion of the display device 100 of FIG. 3 according to aspects of the present disclosure.

Referring to FIG. 4, the second metal layer 160 can extend, with respect to the first hole H1, along an upper surface of one side of the first planarization layer 121, the inside of the first hole H1, and an upper surface of the other side of the first planarization layer 121, wherein the one side and the other side of the first planarization layer 121 are separated by the first hole H1. The contact electrode CTE can extend, with respect to the second hole H2, along an upper surface of one side of the second planarization layer 122, the insides of the second hole H2 and the first hole H1, and an upper surface of the other side of the second planarization layer 122, wherein the one side and the other side of the second planarization layer 122 are separated by the second hole H2.

For example, respective end portions of the second metal layer 160 and the contact electrode CTE can be interposed between organic layers included in the at least one organic layers 120. Accordingly, a height h1 of the at least one organic layer 120, in which the second metal layer 160 and the contact electrode CTE are interposed, can be greater than a height h2 of the moisture permeation prevention structure 170. For example, a height h1 of the at least one organic layer 120 can be further increased by thicknesses of the second metal layer 160 and the contact electrode CTE. As the height h1 of the at least one organic layer 120, which acts as a dam, increases by the thicknesses of the second metal layer 160 and the contact electrode CTE, the encapsulation layer 140 can be more effectively prevented from overflowing.

The examples, aspects, and embodiments of the present disclosure described above will be briefly described as follows.

According to the one or more example embodiments described herein, a display device can include a base substrate including a display area and a non-display area, a first metal layer disposed on the non-display area of the base substrate, a plurality of organic layers disposed on the base substrate and having a hole for exposing a portion of the first metal layer in the non-display area, a second metal layer contacting the first metal layer through the hole, an end portion of the second metal layer being disposed between the organic layers located outside of the hole with respect to the hole, a contact electrode contacting the second metal layer through the hole, an end portion of the contact electrode being disposed between the organic layers located outside of the hole with respect to the hole, a protection layer covering the plurality of organic layers, and an encapsulation layer disposed on the protection layer and including a portion located in the hole.

In one or more aspects, the hole can be formed such that a width of the hole narrows from top to bottom.

In one or more aspects, the plurality of organic layers can include a first planarization layer disposed on the base substrate and having a first hole formed in an area overlapping with the first metal layer, a second planarization layer disposed on the first planarization layer and having a second hole formed in an area overlapping with the first hole, and a bank layer disposed on the second planarization layer and having a third hole formed in an area overlapping with the second hole, the hole can include the first hole, the second hole, and the third hole.

In one or more aspects, the bank layer can include a spacer formed in an upper portion.

In one or more aspects, the second metal layer can be disposed between the first planarization layer and the second planarization layer, and extend, with respect to the first hole, along an upper portion of one side of the first planarization layer, an inside of the first hole, and an upper portion of the other side of the first planarization layer, wherein the one side and the other side of the first planarization layer can be separated by the first hole.

In one or more aspects, an end portion of the second planarization layer can cover respective end portions of the second metal layer and the first flattening layer.

In one or more aspects, the contact electrode can be disposed between the second planarization layer and the bank layer, and extend, with respect to the second hole, along an upper portion of one side of the second planarization layer, respective insides of the second hole and the first hole, and an upper portion of the other side of the second planarization layer, wherein the one side and the other side of the second planarization layer can be separated by the second hole.

In one or more aspects, the display device can further include a second electrode disposed between the bank layer and the protection layer and contacting the contact electrode through the first hole, the second hole, and the third hole.

In one or more aspects, an end portion of the second electrode can be disposed on an inclined surface of at least one of the plurality of organic layers formed by the hole.

In one or more aspects, an end portion of the second electrode can be disposed in the third hole and does not to extend beyond the bank layer.

In one or more aspects, an end portion of the bank layer can cover respective end portions of the contact electrode and the second planarization layer.

In one or more aspects, the second metal layer, the contact electrode, and the second electrode can overlap with each other on an inclined surface of the first planarization layer formed by the hole.

In one or more aspects, the first metal layer, the second metal layer, the contact electrode, and the second electrode can overlap with each other in the hole.

In one or more aspects, the second metal layer and the contact electrode can overlap with each other on an inclined surface of the second planarization layer formed by the hole.

In one or more aspects, the display device can further include a moisture permeation prevention structure spaced apart from the plurality of organic layers.

In one or more aspects, the moisture permeation prevention structure can be in the form of a plurality of layers, and include the same material as one selected from materials included in the plurality of organic layers.

In one or more aspects, the moisture permeation prevention structure can include a first moisture permeation prevention portion, a second moisture permeation prevention portion covering upper and side portions of the first moisture permeation prevention portion, and a third moisture permeation prevention portion covering an upper portion of the second moisture permeation prevention.

In one or more aspects, a height of the plurality of organic layers in which the second metal layer and the contact electrode are interposed can be greater than a height of the moisture permeation prevention structure.

In one or more aspects, the base substrate can include a plurality of inorganic layers, and the moisture permeation prevention structure can over respective upper end portions and side end portions of the inorganic layers.

In one or more aspects, the protection layer can cover the second electrode, the plurality of organic layers, the base substrate, and the moisture permeation prevention structure.

In one or more aspects, the hole can be disposed to surround the display area in the non-display area.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the principles described herein can be applied to other embodiments and applications without departing from the scope of the present disclosure. The above description and the accompanying drawings provide an example of the technical idea of the present invention for illustrative purposes only. That is, the disclosed embodiments are intended to illustrate the scope of the technical idea of the present disclosure.

What is claimed is:

1. A display device comprising:
a base substrate including a display area and a non-display area;
a first metal layer disposed on the non-display area of the base substrate;
a plurality of organic layers disposed on the base substrate and having a hole for exposing a portion of the first metal layer in the non-display area;
a second metal layer contacting the first metal layer through the hole, an end portion of the second metal layer being disposed between the plurality of organic layers located outside of the hole with respect to the hole;
a contact electrode contacting the second metal layer through the hole, an end portion of the contact electrode being disposed between the plurality of organic layers located outside of the hole with respect to the hole;
a protection layer covering the plurality of organic layers; and
an encapsulation layer disposed on the protection layer and including a portion located in the hole.

2. The display device of claim 1, wherein a width of the hole narrows from a top to a bottom of the hole.

3. The display device of claim 1, wherein the plurality of organic layers comprise:
a first planarization layer disposed on the base substrate and having a first hole formed in an area overlapping with the first metal layer,
a second planarization layer disposed on the first planarization layer and having a second hole formed in an area overlapping with the first hole, and
a bank layer disposed on the second planarization layer and having a third hole formed in an area overlapping with the second hole, and
wherein the hole comprises the first hole, the second hole, and the third hole.

4. The display device of claim 3, wherein the bank layer comprises a spacer formed in an upper portion.

5. The display device of claim 3, wherein the second metal layer is disposed between the first planarization layer and the second planarization layer,
wherein the second metal layer extends, with respect to the first hole, along an upper portion of one side of the first planarization layer, an inside of the first hole, and an upper portion of another side of the first planarization layer, and
wherein the one side and the another side of the first planarization layer are separated by the first hole.

6. The display device of claim 5, wherein an end portion of the second planarization layer covers respective end portions of the second metal layer and the first flattening layer.

7. The display device of claim 3, wherein the contact electrode is disposed between the second planarization layer and the bank layer,
wherein the contact electrode extends, with respect to the second hole, along an upper portion of one side of the second planarization layer, respective insides of the second hole and the first hole, and an upper portion of another side of the second planarization layer, and
wherein the one side and the another side of the second planarization layer are separated by the second hole.

8. The display device of claim 7, further comprising a second electrode disposed between the bank layer and the protection layer and contacting the contact electrode through the first hole, the second hole, and the third hole.

9. The display device of claim 8, wherein an end portion of the second electrode is disposed on an inclined surface of at least one of the plurality of organic layers formed by the hole.

10. The display device of claim 8, wherein an end portion of the second electrode is disposed in the third hole and does not to extend beyond the bank layer.

11. The display device of claim 8, wherein an end portion of the bank layer covers respective end portions of the contact electrode and the second planarization layer.

12. The display device of claim 8, wherein the second metal layer, the contact electrode, and the second electrode overlap with each other on an inclined surface of the first planarization layer formed by the hole.

13. The display device of claim 8, wherein the first metal layer, the second metal layer, the contact electrode, and the second electrode overlap with each other in the hole.

14. The display device of claim 3, wherein the second metal layer and the contact electrode overlap with each other on an inclined surface of the second planarization layer formed by the hole.

15. The display device of claim 1, further comprising a moisture permeation prevention structure spaced apart from the plurality of organic layers.

16. The display device of claim 15, wherein the moisture permeation prevention structure includes a plurality of layers, and comprises a same material as one selected from materials included in the plurality of organic layers.

17. The display device of claim 15, wherein the moisture permeation prevention structure comprises:
a first moisture permeation prevention portion,
a second moisture permeation prevention portion covering upper and side portions of the first moisture permeation prevention portion, and
a third moisture permeation prevention portion covering an upper portion of the second moisture permeation prevention portion.

18. The display device of claim 15, wherein a height of the plurality of organic layers in which the second metal layer and the contact electrode are interposed is greater than a height of the moisture permeation prevention structure.

19. The display device of claim 15, wherein the base substrate comprises a plurality of inorganic layers, and the moisture permeation prevention structure covers respective upper end portions and side end portions of the plurality of inorganic layers.

20. The display device of claim 8, further comprising a moisture permeation prevention structure spaced apart from the plurality of organic layers,
wherein the protection layer covers the second electrode, the plurality of organic layers, the base substrate, and the moisture permeation prevention structure.

21. The display device of claim 1, wherein the hole is disposed to surround the display area in the non-display area.
